(19) United States
(12) Patent Application Publication
(10) Pub. No.: US 2026/0150342 A1
(43) Pub. Date: May 28, 2026

(54) NANOSHEET STRUCTURE WITH COMPOSITE SEMICONDUCTOR LINER

(71) Applicant: INTERNATIONAL BUSINESS MACHINES CORPORATION, ARMONK, NY (US)

(72) Inventors: Nicolas Jean Loubet, Guilderland, NY (US); Curtis Scott Durfee, Schenectady, NY (US); Shogo Mochizuki, Mechanicville, NY (US)

(21) Appl. No.: 18/956,950

(22) Filed: Nov. 22, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018; H10D 64/021; H10D 30/6736

(57) ABSTRACT

A microelectronic structure that includes a nanosheet transistor that includes a plurality of channel layers, a gate, and source/drain. An inner spacer liner that is located adjacent to the gate, where the inner spacer liner has a C-shape profile as view perpendicular to a gate direction. An inner spacer located adjacent to inner spacer liner.

### BACKGROUND

The present invention generally relates to the field of microelectronics, and more particularly to the formation of a semiconductor liner located around the inner spacer.

Nanosheet is the lead device architecture in continuing CMOS scaling. However, nanosheet technology has shown issues when scaling down such that as the devices becoming smaller and closer together, they are interfering with each other. During the formation of the inner spacer defects can be formed by the incomplete recessing of sacrificial layers.

### BRIEF SUMMARY

Additional aspects and/or advantages will be set forth in part in the description which follows and, in part, will be apparent from the description, or may be learned by practice of the invention.

A microelectronic structure that includes a nanosheet transistor that includes a plurality of channel layers, a gate, and source/drain. An inner spacer liner that is located adjacent to the gate, where the inner spacer liner has a C-shape profile as view perpendicular to a gate direction. An inner spacer located adjacent to inner spacer liner.

A microelectronic structure includes a nanosheet transistor that includes a plurality of channel layers, a gate, and source/drain. A plurality inner spacer liners, where each of the plurality of inner spacer liners are located adjacent to the gate. Multiple of the plurality of inner spacer liners that are located on a first side of the gate have a C-shape profile as view perpendicular to a gate direction. Multiple of the plurality of inner spacer liners that are located on a second side of the gate have an inverted C-shape profile as view perpendicular to the gate direction. A plurality of inner spacers, where each of the plurality of inner spacers is located adjacent to one of the plurality of inner spacer liners.

A microelectronic structure includes a nanosheet transistor that includes a plurality of channel layers, a gate, and source/drain. A plurality of dielectric liners located on a first side of the gate and located on a second side of the gate. A plurality inner spacer liners, where each of the plurality of inner spacer liners are located adjacent one of the plurality of dielectric liners. Multiple of the plurality of inner spacer liners that are located on the first side of the gate have a C-shape profile as view perpendicular to a gate direction. Multiple of the plurality of inner spacer liners that are located on the second side of the gate have an inverted C-shape profile as view perpendicular to the gate direction. Multiple of the plurality of dielectric liners that are located on the first side of the gate have a C-shape profile as view perpendicular to the gate direction. Multiple of the plurality of dielectric liners that are located on the second side of the gate have an inverted C-shape profile as view perpendicular to the gate direction. A plurality of inner spacers, where each of the plurality of inner spacers is located adjacent to one of the plurality of inner spacer liners.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross-section X of the nanosheet transistor after the formation of the dummy gate, hardmask, and a gate spacer, in accordance with the embodiment of the present invention.

FIG. 3 illustrates a cross-section Y of the gate region after the formation of the dummy gate, hardmask, and a gate spacer, in accordance with the embodiment of the present invention.

FIG. 4 illustrates a cross-section X of the nanosheet transistor after the formation of the source/drain regions and recessing of the sacrificial layers, in accordance with the embodiment of the present invention.

FIG. 5 illustrates a cross-section X of the nanosheet transistor after the formation of an inner spacer liner, in accordance with the embodiment of the present invention.

FIG. 6 illustrates a cross-section X of the nanosheet transistor after the formation of an inner spacer, in accordance with the embodiment of the present invention.

FIG. 7 illustrates a cross-section X of the nanosheet transistor after the etching of the inner spacer liner and the inner spacer, in accordance with the embodiment of the present invention.

FIG. 8 illustrates a cross-section X of the nanosheet transistor after formation of source/drains, and formation of an interlayer dielectric layer, and after a planarization process to remove excess materials, in accordance with the embodiment of the present invention.

FIG. 9 illustrates a cross-section X of the nanosheet transistor after the removal of the dummy gate and the removal of the sacrificial layers, in accordance with the embodiment of the present invention.

FIG. 10 illustrates a cross-section Y of the gate region after the removal of the dummy gate and the removal of the sacrificial layers, in accordance with the embodiment of the present invention.

FIG. 11 illustrates a cross-section X of the nanosheet transistor after formation of the gate, in accordance with the embodiment of the present invention.

FIG. 12 illustrates a cross-section Y of the gate region after formation of the gate, in accordance with the embodiment of the present invention.

FIG. 13 illustrates a cross-section X of the nanosheet transistor after recessing of the gate and the formation of a gate cap, in accordance with the embodiment of the present invention.

FIG. 14 illustrates a cross-section Y of the gate region after recessing the gate and the formation of a gate cap, in accordance with the embodiment of the present invention.

FIG. 15 illustrates a cross-section X of the nanosheet transistor after additional processing of the nanosheet transistor, in accordance with the embodiment of the present invention.

FIG. 16 illustrates a cross-section Y of the gate region after additional processing of the nanosheet transistor, in accordance with the embodiment of the present invention.

FIG. 17 illustrates a cross-section X of an alternative nanosheet transistor after additional processing of the nanosheet transistor, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limited in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. Prior to the formation of the inner spacer in a nanosheet FET a sacrificial layer is recessed. In an ideal scenario, the sacrificial layer is completely recessed without leaving any remaining portions of the sacrificial material in the recessed area. This would allow for the inner spacer to form an ideal seal. However, the ideal scenario does not always occur. For example, portions of the sacrificial material can remain in the recessed area which can develop into a defect when the sacrificial material is replaced with gate materials. Another example is when portions of the sacrificial material can remain in the recessed area that can lead to buried void issues. The present invention is directed towards solving this issue by forming an inner spacer liner around the boundaries of the recessed area (i.e., the area where the sacrificial layer was recessed prior to inner spacer formation). The inner spacer liner can be comprised of a semiconductor material. Additionally, a dielectric liner can be added prior to the formation of the inner spacer liner.

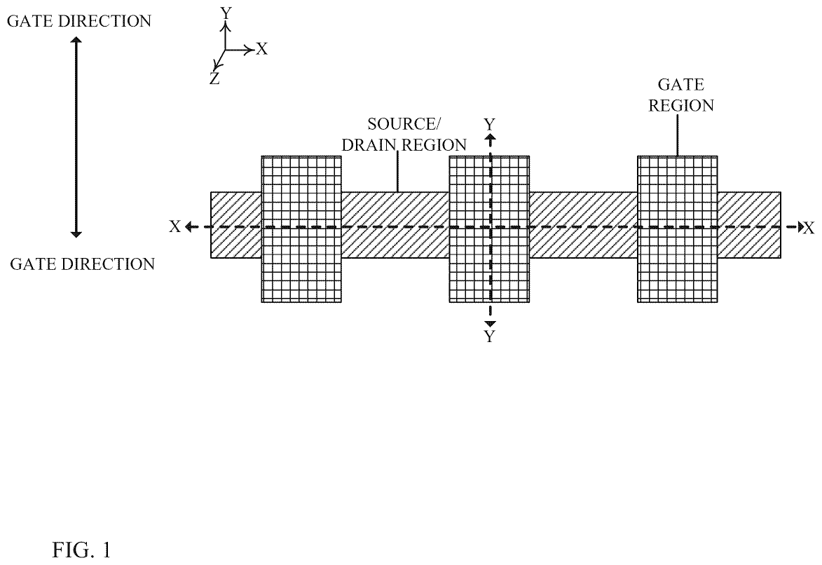

FIG. 1 illustrates a top-down view of multiple devices, in accordance with the embodiment of the present invention. The cross-section X extends horizontally through nanosheet transistors or field-effect-transistors. Cross section Y is perpendicular to cross section X, where cross section Y is through a gate region of the nanosheet transistor or field-effect-transistor. Cross-section X is perpendicular to the gate direction and cross-section Y is parallel to the gate direction.

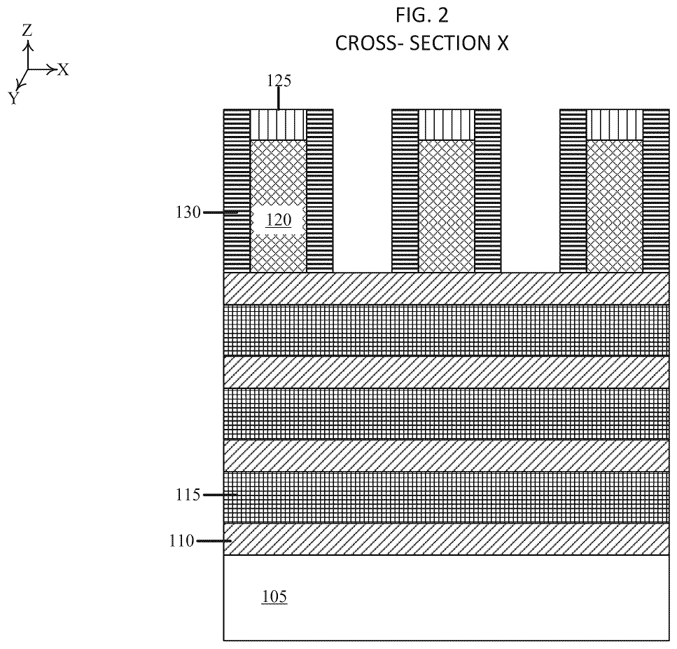

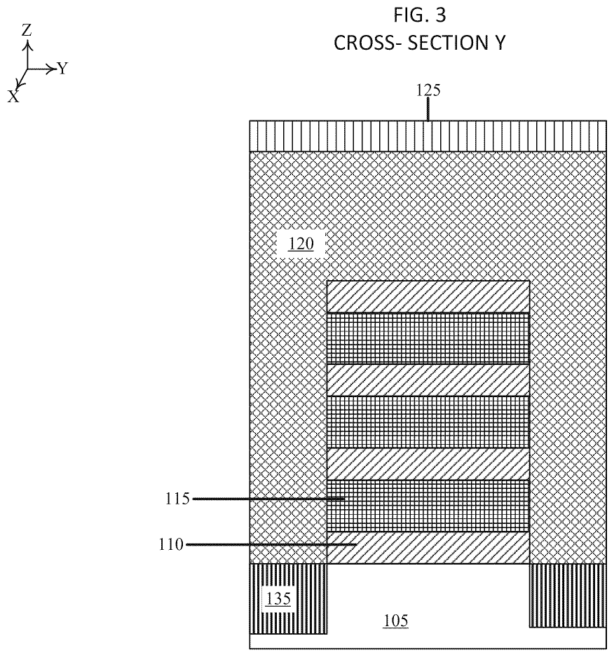

Referring now to FIGS. 2, and 3, a structure is shown during an intermediate step of a method of fabricating after the formation of the dummy gate 120, hardmask 125, and a gate spacer 130. FIG. 2 illustrates the nano stack of the nanosheet transistors that includes a substrate 105, a plurality of layers, a dummy gate 120, a hardmask 125, and gate spacer 130.

The plurality of layers includes alternating layers of channel layers 115 (e.g., nanosheets), and sacrificial layers 110. The plurality of channel layers 115 can be comprised of, for example, Si. The plurality of sacrificial layers 110 can be comprised of SiGe, where Ge is in the percentage of 15 to 35%.

The substrate 105 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

FIG. 2 illustrates that the dummy gate 120 is formed on top of the plurality of layers and the hardmask 125 was formed on top of the dummy gate 120. The hardmask 125 and the dummy gate 120 were patterned to form a plurality of gate regions and the gate spacer 130 is formed along the sides of each of the gate regions. FIG. 3 illustrates a cross-section of one of the gate regions of the nanosheet FET. A plurality of trenches (not shown) was formed in substrate 105 during the processing of the plurality of layers. These trenches (not shown) were filled in with a shallow trench isolation layer 135.

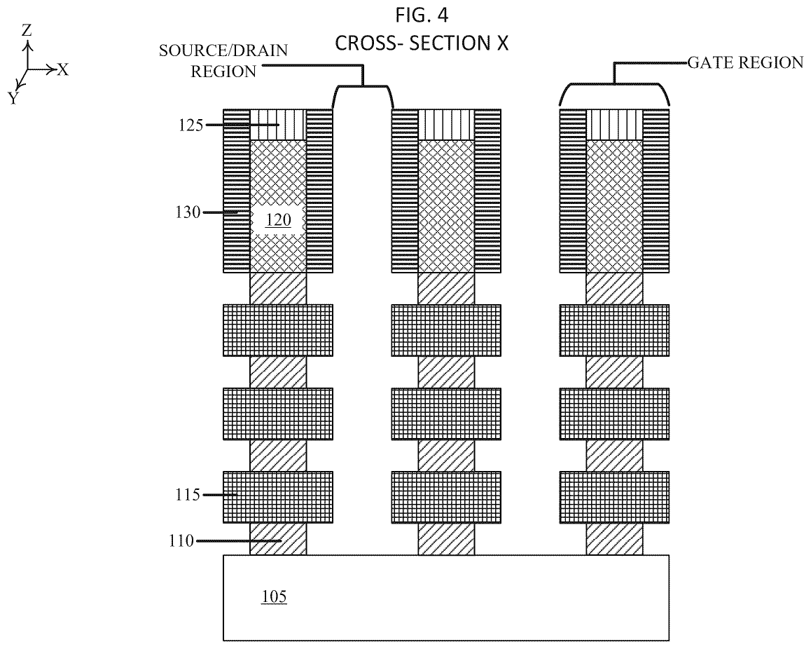

FIG. 4 illustrates the processing stage after the formation of the source/drain regions and recessing of the sacrificial layers 110. The plurality of layers are etched to form a plurality of source/drain regions, where the source/drain regions are located adjacent to the gate regions. The etching of the plurality of layers forms a plurality of stacks, where each stack includes a plurality of channel layers 115 and a plurality of sacrificial layers 110. The sacrificial layers 110 are recessed to form a void/spacer around the ends (as viewed perpendicular to the gate direction as illustrated in FIG. 4) of each of the plurality of channel layers 115.

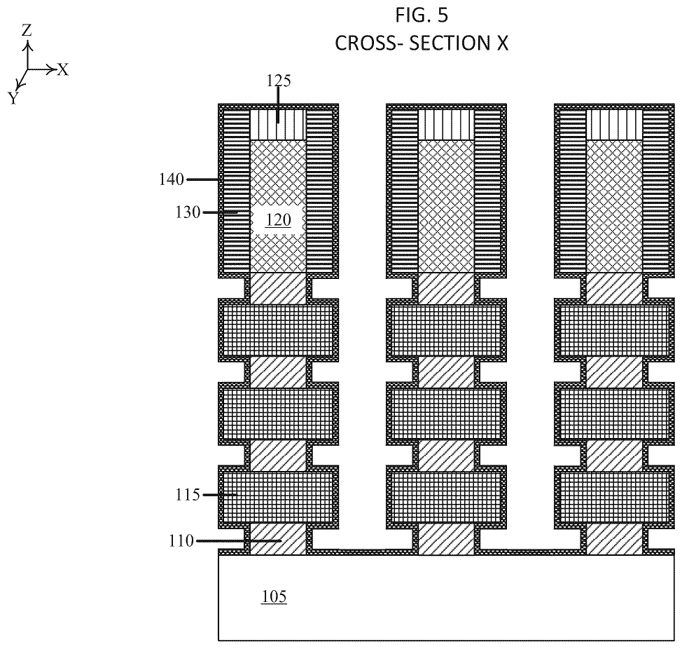

FIG. 5 illustrates the processing stage after the formation of an inner spacer liner 140. An inner spacer liner 140 is formed on the exposed surfaces, for example, the inner spacer liner 140 is formed on the exposed portions of the substrate 105, on the exposed portions of the channel layers 115, along the exposed surfaces of sacrificial layers 110, on the surfaces of gate spacer 130, and on top of the hardmask 125. The inner spacer liner 140 is comprised of a semiconductor such as Si, or another suitable material. The inner spacer liner 140 has a thickness in the range of about 1 to 3 nanometers. The inner spacer liner 140 does not fill the space created by the recessing the sacrificial layers 110.

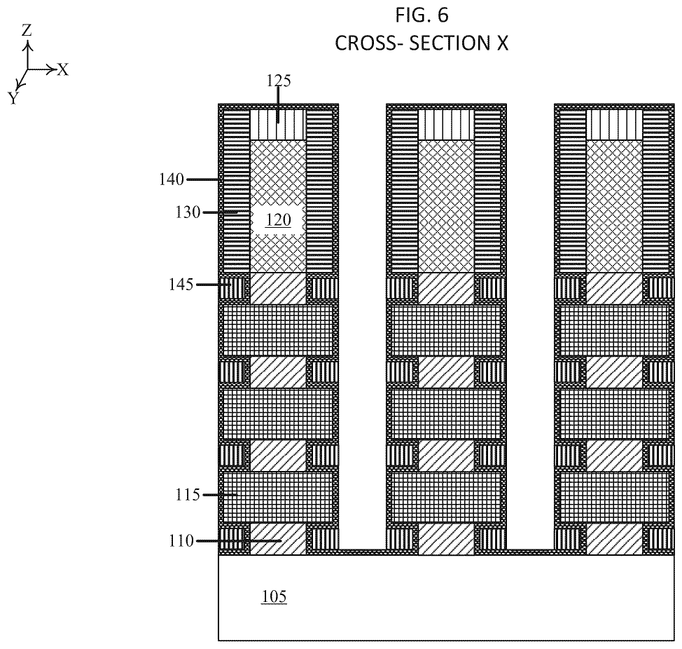

FIG. 6 illustrates the processing stage after the formation of an inner spacer 145. Inner spacer 145 is formed on the inner spacer liner 140. The inner spacer 145 is partially enclosed by the inner spacer liner 140, such that the inner spacer liner 140 is located above and below the inner spacer 145 and along the inner side of the inner spacer 145. The inner side of the inner spacer 145 is the side that is closest to the sacrificial layer 110.

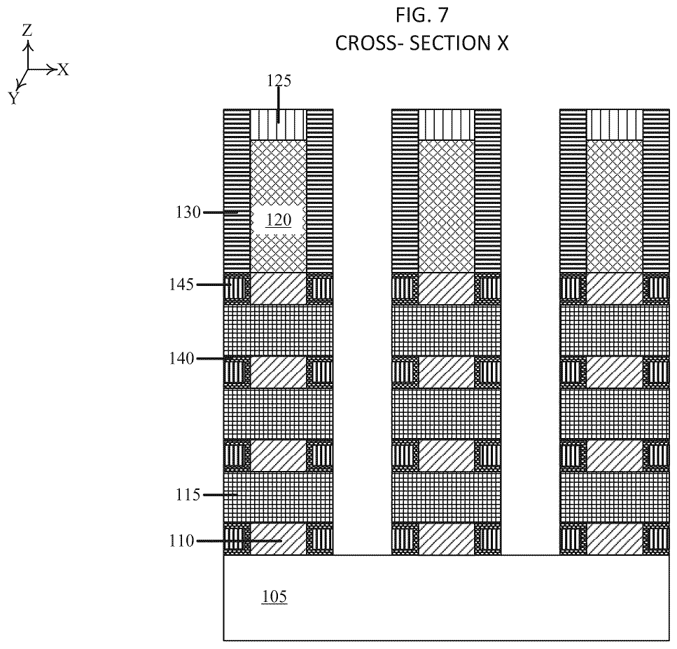

FIG. 7 illustrates the processing stage after the etching of the inner spacer liner 145 and the inner spacer 140. Excess inner spacer liner 140 and some of the inner spacer 145 are removed by an etching process. The exposed surfaces of the inner spacer liner 140 and the inner spacer 145 form a flat or flush surface with the gate spacer 130 and the plurality of channel layers 115. The etching process separates the single inner spacer liner 140 into a plurality of independent inner spacer liners 140. Each of the inner spacer liners 140 are located adjacent to a side of the sacrificial layers 110. Furthermore, each of the inner spacer liners 140 partly enclose the inner spacer 145. The exposed surface of the inner spacer 145 is flush with the exposed surface of the inner spacer liner 140.

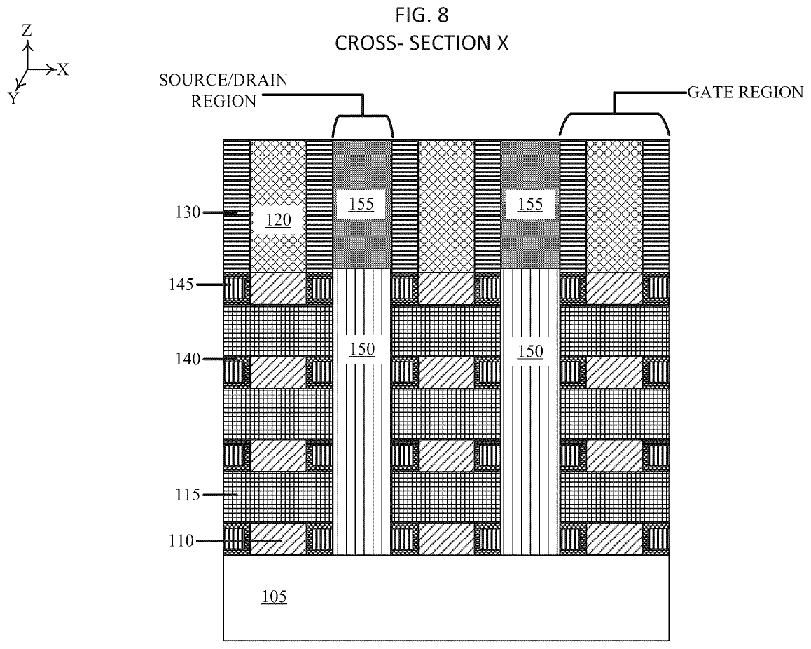

FIG. 8 illustrates the processing stage after formation of source/drains 150, and formation of an interlayer dielectric layer 155, and after a planarization process to remove excess materials. The source/drains 150 are formed in the source/drain regions. The source/drains 150 are epitaxially grown off the exposed surfaces of each of the plurality of channel layers 115. Furthermore, the exposed surfaces of the inner spacer liner 140 acts as an additional growth surface for the source/drains 150. The source/drains 150, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

An interlayer dielectric layer 155 is formed on top of the source/drains 150. A planarization process, for example, chemical mechanical planarization (CMP) is used to remove excess material, such as portions of the interlayer dielectric layer 155, portions of the gate spacer 130, and the hardmask 125. The planarization process creates a uniform/flat/flush top surface that extends across the gate spacer 130, the dummy gate 120, and the interlayer dielectric layer 155.

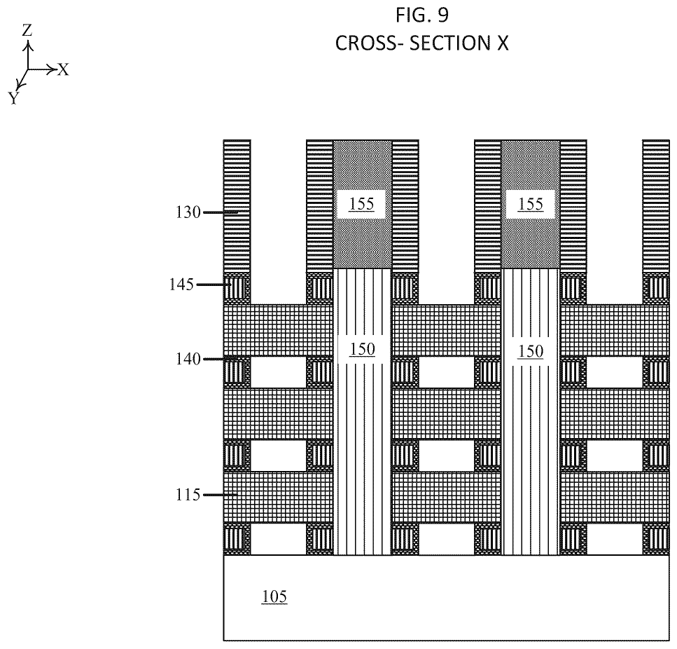

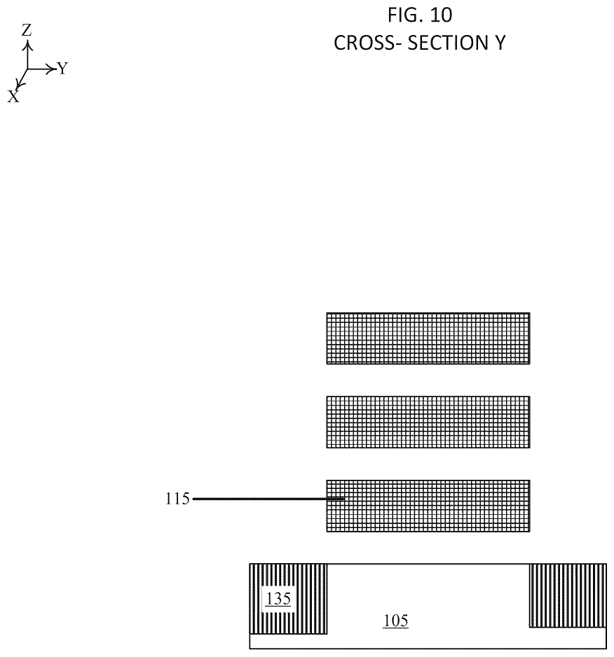

FIGS. 9 and 10 illustrate the processing stage after the removal of the dummy gate 120 and the removal of the sacrificial layers 110. The dummy gate 120 and the sacrificial layers 110 are removed. The removal of these layers exposes multiple surfaces of each of the plurality of channel layers 115. A vertical surface or section of the inner spacer liner 140 that was located adjacent to the sacrificial layers 110 are exposed. The vertical surface or section of the inner spacer liner 140 is located between the empty space and the inner spacer 145.

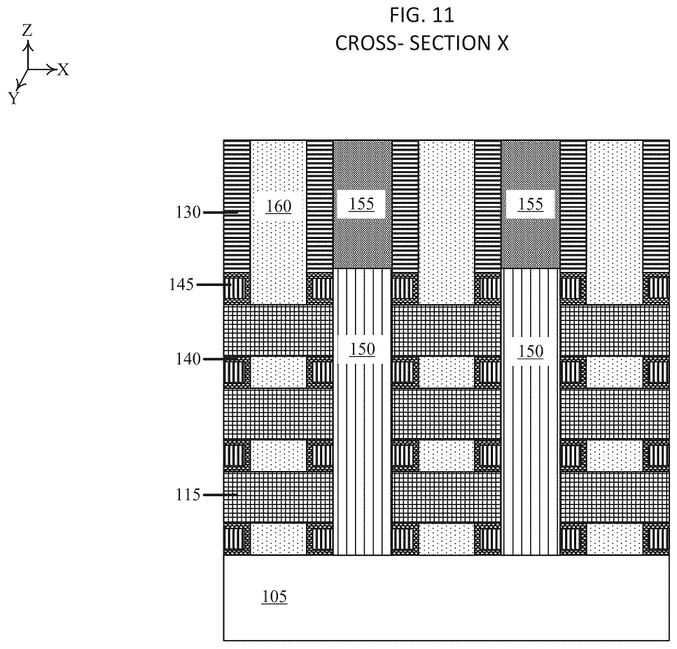

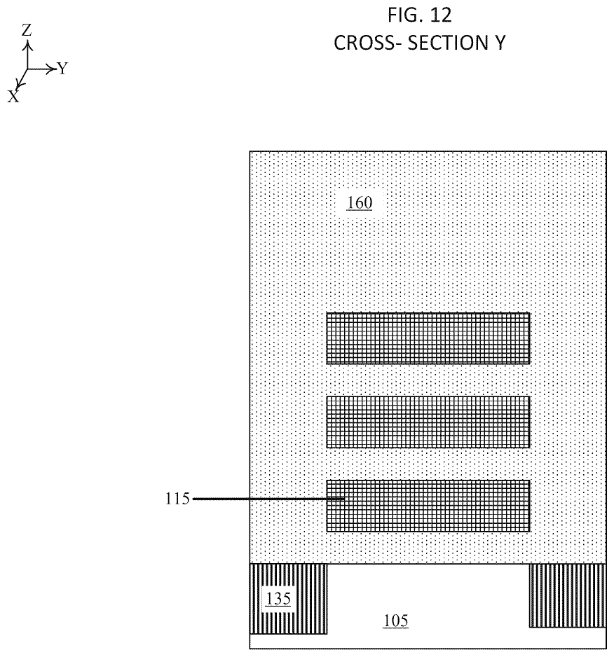

FIGS. 11 and 12 illustrate the processing stage after formation of gate 160. Gate 160 is formed in the empty space created by the removal of the dummy gate 120 and the removal of the sacrificial layers 110. Gate 160 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. Gate 160 is illustrated as one layer for simplistic reasons only. As stated above, gate 160 can include multiple layers from dielectric liners, one or more work function layers, and/or one or more conductive metal fills.

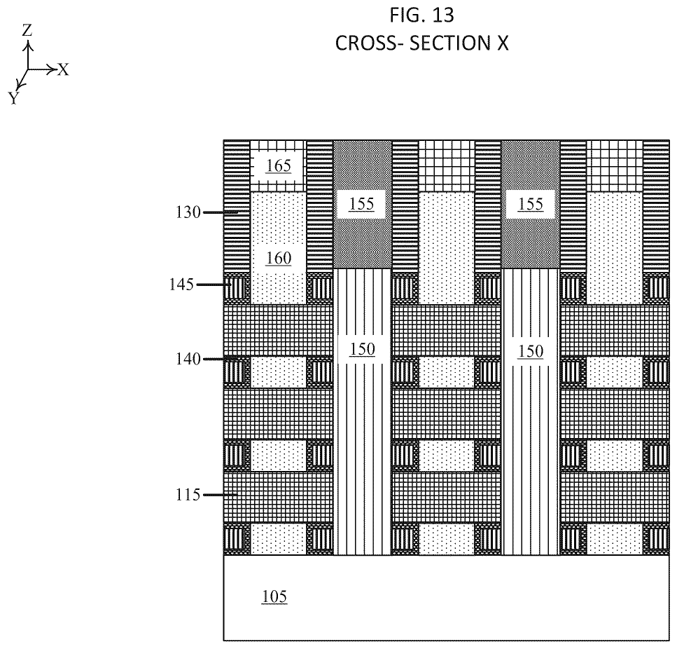

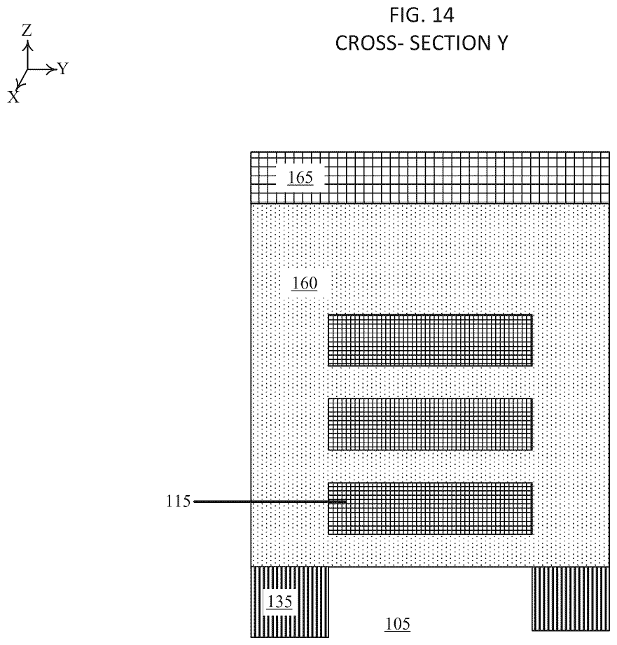

FIGS. 13 and 14 illustrate the processing stage after recessing of gate 160 and the formation of a gate cap 165. Gate 160 is recessed to create an empty space/valley between two adjacent sections of the gate spacer 130. Gate cap 165 is formed on top of gate 160. Gate cap 165 is in contact with gate spacer 130. A planarization process is used to remove excess gate cap 165 material and to create a flush/uniform flat surface between the gate spacer 130, gate cap 165, and interlayer dielectric layer 155.

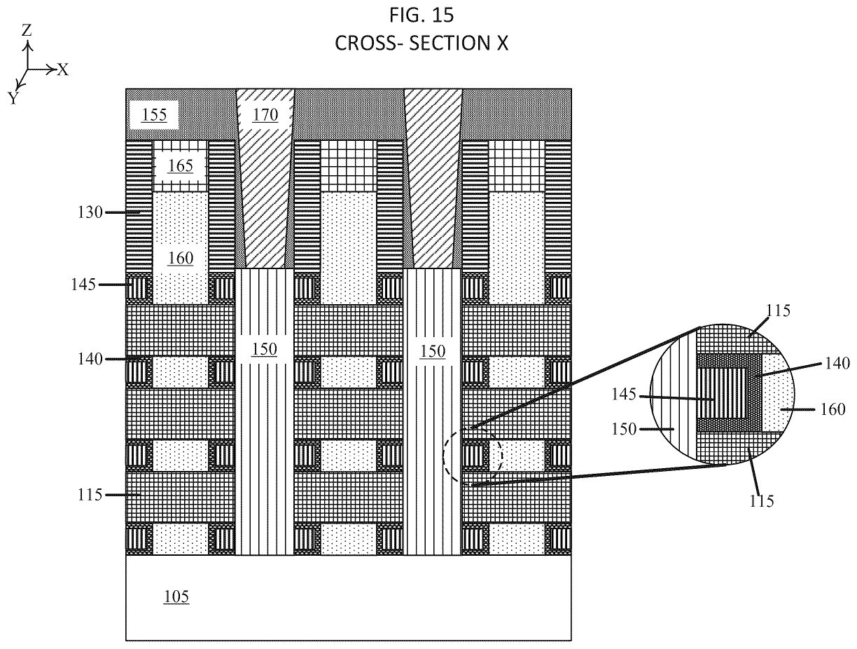

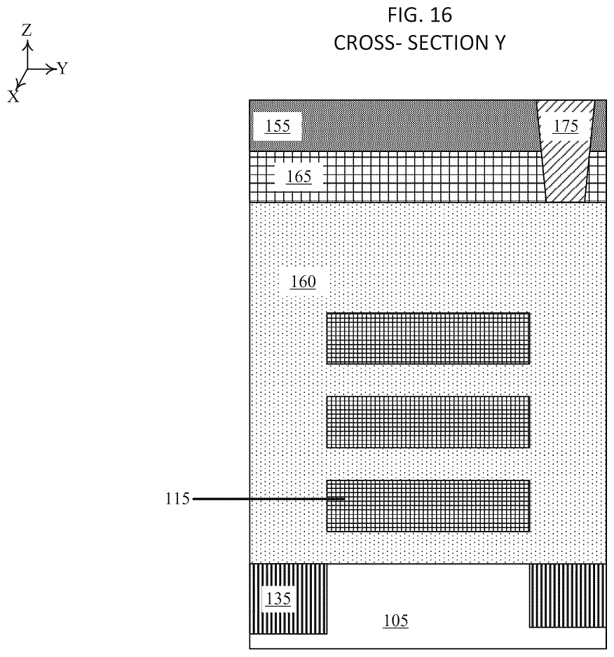

FIGS. 15 and 16 illustrate the processing stage after additional processing of the nanosheet transistor. The height of the interlayer dielectric layer 155 is increased to extend the layer over the top of the gate cap 165 and on top of the gate spacer 130. A plurality of trenches (not shown) is formed in the interlayer dielectric layer 155 and some of the trenches (not shown) can extend into gate cap 165. These trenches are filled with conductive material to form source/drain contacts 170 and gate contact 175. An interconnect (not shown) can be formed on top of the interlayer dielectric layer 155, on top of source/drain contacts 170, and on top of the gate contact 175. The interconnect (not shown) can be comprised of one or more layers, one or more metal lines, and one or more connecting vias. FIG. 15 includes a magnified view of one of the inner spacers 145 that is partially enclosed by inner spacer liner 140. The inner spacer liner 140 is located above and below the inner spacer 145, such that the inner spacer liner 140 is in direct contact with the channel layers 115. Furthermore, the inner spacer liner 140 is located between the inner spacer 145 and gate 160. The inner spacer liner 140 has a C-shape (inverted or noninverted) that cups and surrounds the inner spacer 145.

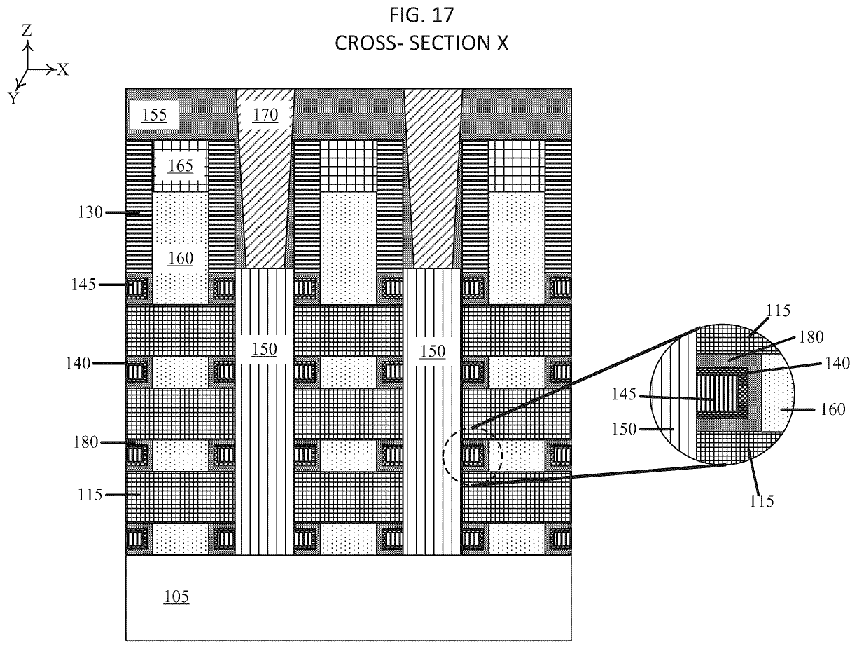

FIG. 17 illustrates the processing stage after additional processing of an alternative nanosheet transistor. The alternative nanosheet transistor illustrated in FIG. 17 is similar to the one illustrated in FIG. 15, therefore similar components are identified with the same reference numbers. FIG. 17 includes the addition of a dielectric liner 180 located adjacent to the inner spacer liner 140. The dielectric liner 180 is located in the space created by the recessing of the sacrificial layers 110. The formation of the dielectric liner 180 occurs prior to the formation of the inner spacer liner 140. The dielectric liner 180 is located between the inner spacer liner 140 and the channel layers 115. Furthermore, the dielectric liner 180 is located between the inner spacer liner 140 and gate 160, see for example the magnified section in FIG. 17. The inner spacer liner 140 has a C-shape (inverted or noninverted) that cups and surrounds the inner spacer 145. The dielectric liner 180 has a C-shape (inverted or noninverted) that cups and surrounds the inner spacer liner 140 and the inner spacer 145.

A microelectronic structure that includes a nanosheet transistor that includes a plurality of channel layers 115, a gate 160, and source/drain 150. An inner spacer liner 140 that is located adjacent to the gate 160, where the inner spacer liner 140 has a C-shape profile as view perpendicular to a gate direction. An inner spacer 145 located adjacent to inner spacer liner 140.

The inner spacer liner 140 is comprised of a semiconductor material. The inner spacer liner 140 is in contact with at a top surface, a bottom surface, and a first side surface of the inner spacer 145. The inner spacer liner 140 is located between the gate 160 and the first side surface of the inner spacer 145. The inner spacer 145 includes a second side surface that is not enclosed by the inner spacer liner 140, where the first side surface is opposite the second side surface. The inner spacer liner 140 and the second side surface of the inner spacer 145 form a flush surface. The flush surface of the inner spacer liner 140 and the inner spacer 140 is in contact with the source/drain 150. The inner spacer liner 140 has a thickness in the range of about 1 to 3 nanometers.

A microelectronic structure includes a nanosheet transistor that includes a plurality of channel layers 115, a gate 160, and source/drain 150. A plurality inner spacer liners 140, where each of the plurality of inner spacer liners 140 are located adjacent to the gate 160. Multiple of the plurality of inner spacer liners 140 that are located on a first side of the gate 160 have a C-shape profile as view perpendicular to a gate direction. Multiple of the plurality of inner spacer liners 140 that are located on a second side of the gate 160 have an inverted C-shape profile as view perpendicular to the gate direction. A plurality of inner spacers 145, where each of the plurality of inner spacers 145 is located adjacent to one of the plurality of inner spacer liners 140.

Each of the plurality of inner spacer liners 140 are comprised of a semiconductor material. Each of the plurality of inner spacer liners 140 is in contact with at a top surface, a bottom surface, and a first side surface of one of the plurality of inner spacers 145. Each of the plurality of inner spacer liners 140 are located between the gate 160 and the first side surface of one of the plurality of inner spacers 145. Each of the inner spacers 145 includes a second side surface that is not enclosed by one of the plurality of inner spacer liners 140. The first side surface is opposite the second side surface. Each of the plurality of inner spacer liners 140 and the second side surface of each of the plurality of inner spacers 145 located on the first side of the gate forms a first flush surface, where each of the plurality of inner spacer liners 140 and the second side surface of each of the plurality of inner spacers 145 located on the second side of the gate forms a second flush surface. The first flush is in contact with the source/drain 150. Each of the plurality of inner spacer liners 145 has a thickness in the range of about 1 to 3 nanometers.

A microelectronic structure includes a nanosheet transistor that includes a plurality of channel layers 115, a gate 160, and source/drain 150. A plurality of dielectric liners 180 located on a first side of the gate and located on a second side of the gate 160. A plurality inner spacer liners 145, where each of the plurality of inner spacer liners 140 are located adjacent one of the plurality of dielectric liners 180. Multiple of the plurality of inner spacer liners 140 that are located on the first side of the gate 160 have a C-shape profile as view perpendicular to a gate direction. Multiple of the plurality of inner spacer liners 140 that are located on the second side of the gate 160 have an inverted C-shape profile as view perpendicular to the gate direction. Multiple of the plurality of dielectric liners 180 that are located on the first side of the gate 160 have a C-shape profile as view perpendicular to the gate direction. Multiple of the plurality of dielectric liners 180 that are located on the second side of the gate 160 have an inverted C-shape profile as view perpendicular to the gate direction. A plurality of inner spacers 145, where each of the plurality of inner spacers 145 is located adjacent to one of the plurality of inner spacer liners 140.

Each of the plurality of inner spacer liners 140 are comprised of a semiconductor material.

Each of the plurality of inner spacer liners 140 is in contact with at a top surface, a bottom surface, and a side surface of one of the plurality of inner spacers 145. Each of the plurality of dielectric liners 180 is in contact with a top surface, a bottom surface, and a side surface of each of the plurality of inner spacer liners 140.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet transistor that includes a plurality of channel layers, a gate, and source/drain;
an inner spacer liner that is located adjacent to the gate, wherein the inner spacer liner has a C-shape profile as view perpendicular to a gate direction; and
an inner spacer located adjacent to inner spacer liner.

2. The microelectronic structure of claim 1, wherein the inner spacer liner is comprised of a semiconductor material.

3. The microelectronic structure of claim 1, wherein the inner spacer liner is in contact with at a top surface, a bottom surface, and a first side surface of the inner spacer.

4. The microelectronic structure of claim 3, wherein the inner spacer liner is located between the gate and the first side surface of the inner spacer.

5. The microelectronic structure of claim 4, where the inner spacer includes a second side surface that is not enclosed by the inner spacer liner, wherein the first side surface is opposite the second side surface.

6. The microelectronic structure of claim 5, wherein the inner spacer liner and the second side surface of the inner spacer form a flush surface.

7. The microelectronic structure of claim 6, wherein the flush surface of the inner spacer liner and the inner spacer is in contact with the source/drain.

8. The microelectronic structure of claim 7, wherein the inner spacer liner has a thickness in the range of about 1 to 3 nanometers.

9. The microelectronic structure of claim 1, wherein the inner spacer liner has a thickness in the range of about 1 to 3 nanometers.

10. A microelectronic structure comprising:
a nanosheet transistor that includes a plurality of channel layers, a gate, and source/drain;
a plurality inner spacer liners, wherein each of the plurality of inner spacer liners are located adjacent to the gate, wherein multiple of the plurality of inner spacer liners that are located on a first side of the gate have a C-shape profile as view perpendicular to a gate direction, wherein multiple of the plurality of inner spacer liners that are located on a second side of the gate have an inverted C-shape profile as view perpendicular to the gate direction; and
a plurality of inner spacers, wherein each of the plurality of inner spacers is located adjacent to one of the plurality of inner spacer liners.

11. The microelectronic structure of claim 10, wherein each of the plurality of inner spacer liners are comprised of a semiconductor material.

12. The microelectronic structure of claim 10, wherein each of the plurality of inner spacer liners is in contact with at a top surface, a bottom surface, and a first side surface of one of the plurality of inner spacers.

13. The microelectronic structure of claim 12, wherein each of the plurality of inner spacer liners are located between the gate and the first side surface of one of the plurality of inner spacers.

14. The microelectronic structure of claim 13, where each of the inner spacers includes a second side surface that is not enclosed by one of the plurality of inner spacer liners, wherein the first side surface is opposite the second side surface.

15. The microelectronic structure of claim 14, wherein each of the plurality of inner spacer liners and the second side surface of each of the plurality of inner spacers located on the first side of the gate forms a first flush surface, wherein each of the plurality of inner spacer liners and the second side surface of each of the plurality of inner spacers located on the second side of the gate forms a second flush surface.

16. The microelectronic structure of claim 15, wherein the first flush is in contact with the source/drain.

17. The microelectronic structure of claim 16, wherein each of the plurality of inner spacer liners has a thickness in the range of about 1 to 3 nanometers.

18. The microelectronic structure of claim 10, wherein each of the plurality of inner spacer liners has a thickness in the range of about 1 to 3 nanometers.

19. A microelectronic structure comprising:
a nanosheet transistor that includes a plurality of channel layers, a gate, and source/drain;
a plurality of dielectric liners located on a first side of the gate and located on a second side of the gate;
a plurality inner spacer liners, wherein each of the plurality of inner spacer liners are located adjacent one of the plurality of dielectric liners, wherein multiple of the plurality of inner spacer liners that are located on the first side of the gate have a C-shape profile as view perpendicular to a gate direction, wherein multiple of the plurality of inner spacer liners that are located on the second side of the gate have an inverted C-shape profile as view perpendicular to the gate direction, wherein multiple of the plurality of dielectric liners that are located on the first side of the gate have a C-shape profile as view perpendicular to the gate direction, wherein multiple of the plurality of dielectric liners that are located on the second side of the gate have an inverted C-shape profile as view perpendicular to the gate direction; and
a plurality of inner spacers, wherein each of the plurality of inner spacers is located adjacent to one of the plurality of inner spacer liners.

20. The microelectronic structure of claim 19, wherein each of the plurality of inner spacer liners are comprised of a semiconductor material, wherein each of the plurality of inner spacer liners is in contact with at a top surface, a bottom surface, and a side surface of one of the plurality of inner spacers, wherein each of the plurality of dielectric liners is in contact with a top surface, a bottom surface, and a side surface of each of the plurality of inner spacer liners.
